(19) United States
(12) Patent Application Publication
(10) Pub. No.: US 2026/0106123 A1
(43) Pub. Date: Apr. 16, 2026

(54) PLASMA PROCESSING APPARATUS

(71) Applicant: Tokyo Electron Limited, Tokyo (JP)

(72) Inventors: Ryuta HIGUCHI, Miyagi (JP); Yuji KITAMURA, Miyagi (JP)

(73) Assignee: Tokyo Electron Limited, Tokyo (JP)

(21) Appl. No.: 19/422,508

(22) Filed: Dec. 17, 2025

Related U.S. Application Data
(63) Continuation of application No. PCT/JP2024/004034, filed on Feb. 7, 2024.

(30) Foreign Application Priority Data
Jun. 27, 2023 (JP) 2023-104894

(51) Int. Cl. H01J 37/32

(52) U.S. Cl. CPC H01J 37/32935; H01J 37/32183

(57) ABSTRACT

A plasma processing apparatus includes a chamber, an RF power supply, a measuring instrument configured to periodically or continuously determine an RF reflection characteristic at a node between the chamber and the RF power supply, a storage configured to store a static characteristic, and a controller configured to execute a plasma ignition determination sequence. The plasma ignition determination sequence includes comparing the RF reflection characteristic periodically or continuously determined with the static characteristic stored in the storage, determining that a plasma is not ignited in the chamber when a difference between the RF reflection characteristic and the static characteristic is equal to or less than a threshold value, and determining that the plasma is ignited in the chamber when the difference is larger than the threshold value.

### CROSS-REFERENCE TO RELATED APPLICATIONS

This application is a bypass continuation application of international application No. PCT/JP2024/004034 having an international filing date of Feb. 7, 2024 and designating the United States, the international application being based upon and claiming the benefit of priority from Japanese Patent Application No. 2023-104894, filed on Jun. 27, 2023, the entire contents of each of which are incorporated herein by reference.

### BACKGROUND

### Field

An exemplary embodiment of the present disclosure relates to a plasma processing apparatus.

### Description of Related Art

JP2011-202973A discloses a method of calibrating an RF measurement apparatus that measures an RF parameter in a chamber.

### SUMMARY

In one exemplary embodiment of the present disclosure, there is provided a plasma processing apparatus including: a chamber; an RF power supply coupled to the chamber; a measuring instrument configured to periodically or continuously determine an RF reflection characteristic at a node between the chamber and the RF power supply; a storage configured to store a static characteristic, the static characteristic being the RF reflection characteristic at the node when a low output RF signal is supplied from the RF power supply to the chamber, the low output RF signal having power to an extent that a plasma is not ignited in the chamber; and a controller configured to execute a plasma ignition determination sequence, the plasma ignition determination sequence including comparing the RF reflection characteristic periodically or continuously determined with the static characteristic stored in the storage, determining that the plasma is not ignited in the chamber when a difference between the compared RF reflection characteristic and the static characteristic is equal to or less than a threshold value, and determining that the plasma is ignited in the chamber when the difference between the compared RF reflection characteristic and the static characteristic is larger than the threshold value.

### BRIEF DESCRIPTION OF DRAWINGS

The scope of the present disclosure is best understood from the following detailed description of exemplary embodiments when read in conjunction with the accompanying drawings.

FIG. 1 is a diagram for describing a configuration example of a plasma processing system.

FIG. 2 is a diagram for describing a configuration example of an inductively coupled plasma processing apparatus.

FIG. 3 is a diagram illustrating an example of an RF system.

FIG. 4 is a diagram illustrating another example of the RF system.

FIG. 5 is a flowchart illustrating an example of a static characteristic determination sequence.

FIG. 6 is a diagram illustrating an example of a static characteristic.

FIG. 7 is a flowchart illustrating an example of a plasma ignition determination sequence.

FIG. 8 is a diagram for describing an example of the plasma ignition determination sequence.

### DETAILED DESCRIPTION

Hereinafter, each embodiment of the present disclosure will be described.

In one exemplary embodiment, there is provided a plasma processing apparatus including: a chamber; an RF power supply coupled to the chamber; a measuring instrument configured to periodically or continuously determine an RF reflection characteristic at a node between the chamber and the RF power supply; a storage configured to store a static characteristic, the static characteristic being the RF reflection characteristic at the node when a low output RF signal is supplied from the RF power supply to the chamber, the low output RF signal having power to an extent that a plasma is not ignited in the chamber; and a controller configured to execute a plasma ignition determination sequence, the plasma ignition determination sequence including comparing the RF reflection characteristic periodically or continuously determined with the static characteristic stored in the storage, determining that the plasma is not ignited in the chamber when a difference between the compared RF reflection characteristic and the static characteristic is equal to or less than a threshold value, and determining that the plasma is ignited in the chamber when the difference between the compared RF reflection characteristic and the static characteristic is larger than the threshold value.

In one exemplary embodiment, the RF reflection characteristic is determined from a voltage and a current detected at the node.

In one exemplary embodiment, the static characteristic includes the RF reflection characteristic for each frequency of the low output RF signal.

In one exemplary embodiment, the RF reflection characteristic includes any one or more of (a) a power ratio of a traveling wave and a reflected wave, (b) a resistance component (Ω) of an impedance, (c) a reflection coefficient, (d) a return loss (dB), and (e) an S parameter (dB) at the node.

In one exemplary embodiment, the impedance matching circuit connected between the chamber and the measuring instrument is further provided.

In one exemplary embodiment, the plasma processing apparatus further includes: an impedance matching circuit connected between the RF power supply and the measuring instrument.

In one exemplary embodiment, the controller is configured to further execute a static characteristic determination sequence, and the static characteristic determination sequence includes supplying a plurality of low output RF signals from the RF power supply to the chamber in sequence, the plurality of low output RF signals having frequencies different from each other, respectively, acquiring the RF reflection characteristic for each frequency in the measuring instrument, and storing the acquired RF reflection characteristic for each frequency in the storage as the static characteristic.

In one exemplary embodiment, the static characteristic determination sequence is executed in a state where the plasma is not formed in the chamber, and the low output RF signal has power of less than 10 W.

In one exemplary embodiment, the plasma processing apparatus further includes: another RF power supply configured to generate a source RF signal to form the plasma in the chamber, in which the static characteristic determination sequence is executed in a state where the plasma is formed in the chamber by the source RF signal supplied from the other RF power supply, and the low output RF signal has power of less than 1 W.

In one exemplary embodiment, the static characteristic determination sequence is periodically executed based on an operation time of the RF power supply.

In one exemplary embodiment, the controller determines a frequency of an RF ignition signal used for igniting the plasma in the chamber based on the static characteristic stored in the storage.

In one exemplary embodiment, the frequency of the RF ignition signal is selected from one or a plurality of frequencies indicating a distinctive RF reflection characteristic in the static characteristic.

In one exemplary embodiment, the controller is configured to transition to a matching operation using the impedance matching circuit when it is determined that the plasma is ignited in the chamber.

In one exemplary embodiment, there is provided a plasma processing apparatus including: a chamber; an RF power supply coupled to the chamber; a measuring instrument configured to periodically or continuously determine an RF reflection characteristic at a node between the chamber and the RF power supply; a storage; and a controller configured to execute a static characteristic determination sequence, the static characteristic determination sequence including supplying a plurality of low output RF signals from the RF power supply to the chamber in sequence, the plurality of low output RF signals having frequencies different from each other, respectively, and having power to an extent that a plasma is not ignited in the chamber, acquiring the RF reflection characteristic for each frequency in the measuring instrument, and storing the acquired RF reflection characteristic for each frequency in the storage.

In one exemplary embodiment, the static characteristic determination sequence is executed in a state where the plasma is not formed in the chamber, and the low output RF signal has power of less than 10 W.

In one exemplary embodiment, the plasma processing apparatus further includes: another RF power supply configured to generate a source RF signal to form the plasma in the chamber, in which the static characteristic determination sequence is executed in a state where the plasma is formed in the chamber by the source RF signal supplied from the other RF power supply, and the low output RF signal has power of less than 1 W.

In one exemplary embodiment, the static characteristic determination sequence is periodically executed based on an operation time of the RF power supply.

In one exemplary embodiment, there is provided a plasma processing apparatus including: a chamber; an RF power supply coupled to the chamber; a measuring instrument configured to periodically or continuously determine an RF reflection characteristic at a node between the chamber and the RF power supply; a storage configured to store a static characteristic, the static characteristic being the RF reflection characteristic at the node when an RF signal is supplied from the RF power supply to the chamber under a condition in which a plasma is not ignited; and a controller configured to execute a plasma ignition determination sequence, the plasma ignition determination sequence including comparing the RF reflection characteristic periodically or continuously determined with the static characteristic stored in the storage, determining that the plasma is not ignited in the chamber when a difference between the compared RF reflection characteristic and the static characteristic is equal to or less than a threshold value, and determining that the plasma is ignited in the chamber when the difference between the compared RF reflection characteristic and the static characteristic is larger than the threshold value.

In one exemplary embodiment, the controller is configured to further execute a static characteristic determination sequence, and the static characteristic determination sequence includes supplying a plurality of low output RF signals from the RF power supply to the chamber in sequence under a condition in which the plasma is not ignited, the plurality of low output RF signals having frequencies different from each other, respectively, acquiring the RF reflection characteristic for each frequency in the measuring instrument, and storing the acquired RF reflection characteristic for each frequency in the storage as the static characteristic.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### <Configuration Example of Plasma Processing System>

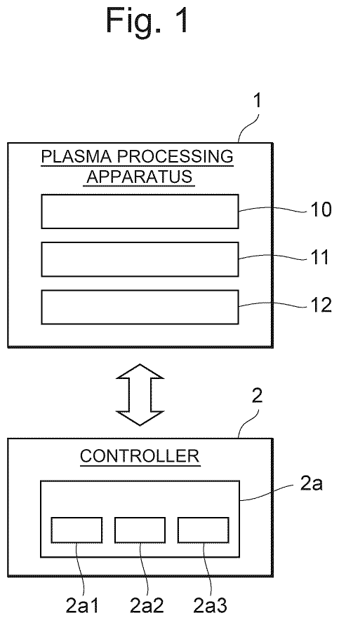

FIG. 1 is a diagram for describing a configuration example of a plasma processing system. In an embodiment, the plasma processing system includes a plasma processing apparatus 1 and a controller 2 (herein controller means the same as controller circuitry). The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space, and at least one gas exhaust port for exhausting the gas from the plasma processing space. The gas supply port is connected to a gas supply 20, described later, and the gas exhaust port is connected to an exhaust system 40, described later. The substrate support 11 is disposed in the plasma processing space and has a substrate support surface for supporting a substrate.

The plasma generator 12 is configured to form plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHZ. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or all of the controller 2 may be configured as a system outside the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired through a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with each element of the plasma processing apparatus 1 via a communication line such as a local area network (LAN). The controller/controller circuitry 2 can be programmable circuitry (e.g., embedded processor) or fixed circuitry (e.g., ASIC or PAL). In an exemplary embodiment, the controller/controller circuitry 2 can include one or more programmable processors/controllers.

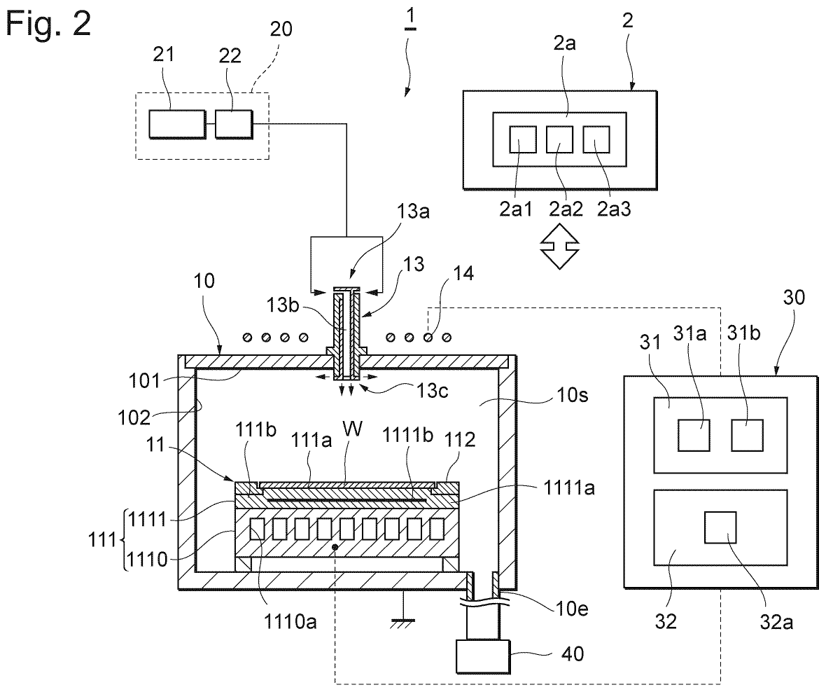

Next, a configuration example of the inductively coupled plasma processing apparatus as an example of the plasma processing apparatus 1 will be described. FIG. 2 is a diagram for describing the configuration example of the inductively coupled plasma processing apparatus.

The inductively coupled plasma processing apparatus 1 includes a plasma processing chamber 10, a gas supply 20, a power supply 30, and an exhaust system 40. The plasma processing chamber 10 includes a dielectric window 101. In addition, the plasma processing apparatus 1 includes a substrate support 11, a gas introducer, and an antenna 14. The substrate support 11 is disposed in the plasma processing chamber 10. The antenna 14 is disposed on or above the plasma processing chamber 10 (that is, on or above the dielectric window 101). The plasma processing chamber 10 has a plasma processing space 10s defined by the dielectric window 101, a side wall 102 of the plasma processing chamber 10, and the substrate support 11. The plasma processing chamber 10 is grounded.

The substrate support 11 includes a main body 111 and a ring assembly 112. The main body 111 has a center region 111a for supporting the substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member (herein “member” means the same as “structure”). The conductive member of the base 1110 may function as a bias electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to a RF power supply 31 and/or a DC power supply 32, which will be described later, may be disposed in the ceramic member 1111a. In this case, at least one RF/DC electrode functions as the bias electrode. The conductive member of the base 1110 and at least one RF/DC electrode may function as a plurality of bias electrodes. Further, the electrostatic electrode 1111b may function as the bias electrode. Therefore, the substrate support 11 includes at least one bias electrode.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module (herein temperature-controlled module means the same as temperature-controlled structure) may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The gas introducer is configured to introduce at least one processing gas from the gas supply 20 into the plasma processing space 10s. In an embodiment, the gas introducer includes a center gas injector (CGI) 13. The center gas injector 13 is disposed above the substrate support 11 and is attached to a center opening portion formed in the dielectric window 101. The center gas injector 13 has at least one gas supply port 13a, at least one gas passage 13b, and at least one gas introduction port 13c. The processing gas supplied to the gas supply port 13a passes through the gas passage 13b and is introduced into the plasma processing space 10s from the gas introduction port 13c. In addition, the gas introducer may include one or a plurality of side gas injectors (SGI) attached to one or a plurality of opening portions formed in the side wall 102 in addition to or instead of the center gas injector 13.

The gas supply 20 may include at least one gas source 21 and at least one flow rate controller 22. In an embodiment, the gas supply 20 is configured to supply at least one processing gas from the gas sources 21 each corresponding thereto to the gas introducer via the flow rate controllers 22 each corresponding thereto. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one bias electrode and the antenna 14. As a result, plasma is formed from at least one processing gas supplied to the plasma processing space 10s. Therefore, the RF power supply 31 may function as at least a part of the plasma generator 12. Further, by supplying the bias RF signal to at least one bias electrode, the bias potential is generated on the substrate W, and ions in the formed plasma are able to be drawn into the substrate W.

In an embodiment, the RF power supply 31 includes a first RF generator 31a and a second RF generator 31b. The first RF generator 31a is coupled to the antenna 14 via at least one impedance matching circuit and is configured to generate the source RF signal (source RF power) for plasma formation. In an embodiment, the source RF signal has a frequency in the range of 10 MHz to 150 MHz. In an embodiment, the first RF generator 31a may be configured to generate a plurality of source RF signals having different frequencies. The generated one or plurality of source RF signals is supplied to the antenna 14.

The second RF generator 31b is coupled to at least one bias electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in the range of 100 kHz to 60 MHz. In an embodiment, the second RF generator 31b may be configured to generate a plurality of bias RF signals having different frequencies. The generated one or plurality of bias RF signals is supplied to at least one bias electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a bias DC generator 32a. In an embodiment, the bias DC generator 32a is connected to at least one bias electrode and is configured to generate the bias DC signal. The generated bias DC signal is applied to at least one bias electrode.

In various embodiments, the bias DC signal may be pulsed. In this case, a sequence of voltage pulses is applied to at least one bias electrode. The voltage pulse may have a pulse waveform having a rectangular shape, a trapezoidal shape, a triangular shape, or a combination thereof. In an embodiment, the waveform generator for generating the sequence of voltage pulses from the DC signal is connected between the bias DC generator 32a and at least one bias electrode. Therefore, the bias DC generator 32a and the waveform generator configure the voltage pulse generator. The voltage pulse may have a positive polarity or a negative polarity. In addition, the sequence of voltage pulses may include one or a plurality of positively-polarized voltage pulses and one or a plurality of negatively-polarized voltage pulses in one cycle. The bias DC generator 32a may be provided in addition to the RF power supply 31 or may be provided in place of the second RF generator 31b.

The antenna 14 includes one or a plurality of coils. In an embodiment, the antenna 14 may include an outer coil and an inner coil disposed coaxially. In this case, the RF power supply 31 may be connected to both the outer coil and the inner coil, or may be connected to any one of the outer coil and the inner coil. In the former case, the same RF generator may be connected to both the outer coil and the inner coil, or separate RF generators may be connected to the outer coil and the inner coil separately.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### <Example of RF System>

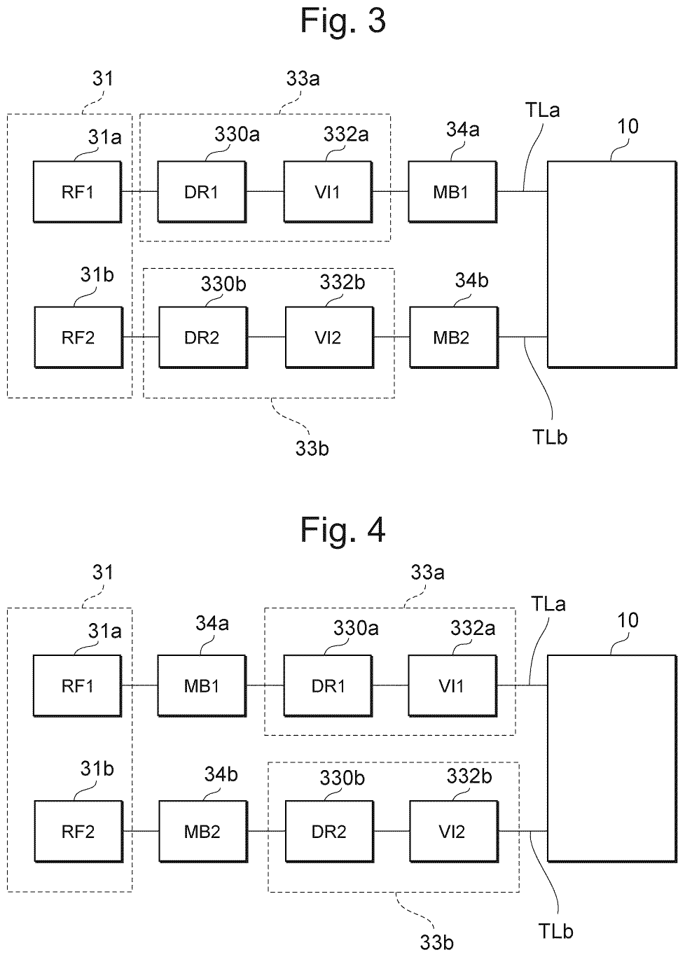

FIG. 3 is a diagram illustrating an example of a system configuration (hereinafter, also referred to as an “RF system”) from an RF power supply 31 to the chamber 10. As illustrated in FIG. 3, a first RF generator (RF1) 31a is connected to the plasma processing chamber 10 (hereinafter, also referred to as a “chamber 10”) via a first transmission line TLa. The first transmission line TLa is a signal line through which a first RF signal (source RF signal) generated by the first RF generator 31a propagates. In the first transmission line TLa, a first RF measurement unit 33a and a first matching circuit 34a are disposed in this order from upstream (RF power supply 31) to downstream (chamber 10). That is, the first RF generator 31a of the RF power supply 31 is coupled to the chamber 10 via the first RF measurement unit 33a and the first matching circuit 34a on the first transmission line TLa.

The first RF measurement unit 33a is configured to periodically or continuously determine an RF reflection characteristic of the first RF signal propagating through the first transmission line TLa. The RF reflection characteristic is a parameter related to a return amount (power of a reflected wave) with respect to an output (power of a traveling wave) of the RF signal in the transmission line. Details of the RF reflection characteristic will be described later.

The first RF measurement unit 33a includes a first directional coupler (DR1) 330a and a first VI sensor (VI1) 332a.

The first directional coupler 330a and the first VI sensor 332a detect signal information for determining the RF reflection characteristics of the first RF signal, respectively. The signal information detected by the first directional coupler 330a includes, for example, information on a power (Pf) of the traveling wave and a power (Pr) of a reflected wave of the first RF signal at an input end (node) of the first matching circuit 34a. The signal information detected by the first VI sensor 332a includes, for example, information on an effective value (V) of a voltage, an effective value (I) of a current, and a phase difference (θ) between the voltage and the current of the first RF signal at the input end (node) of the first matching circuit 34a.

The first matching circuit 34a is configured to match an impedance of the chamber 10 and an impedance of the first RF generator 31a. The first matching circuit 34a includes a variable reactance element (for example, a variable capacitor, a variable inductor, or the like). The variable reactance element of the first matching circuit 34a is controlled, and thus the impedance of the first RF generator 31a with respect to the chamber 10 is controlled.

As illustrated in FIG. 3, a second RF generator (RF2) 31b is connected to the chamber 10 via a second transmission line TLb. The second transmission line TLb is a signal line through which a second RF signal (bias signal) generated by the second RF generator 31b propagates. In the second transmission line TLb, a second RF measurement unit 33b and a second matching circuit 34b are disposed in this order from upstream to downstream. That is, the second RF generator 31b of the RF power supply 31 is coupled to the chamber 10 via the second RF measurement unit 33b and the second matching circuit 34b on the second transmission line TLb. Each configuration of the second RF measurement unit 33b and the second matching circuit 34b may be the same as each configuration of the first RF measurement unit 33a and the first matching circuit 34a which are described above.

FIG. 4 is a diagram illustrating another example of the RF system. In the example illustrated in FIG. 4, a positional relationship between the RF measurement units (33a and 33b) and the matching circuits (34a and 34b) is opposite to the example illustrated in FIG. 3. That is, in the example illustrated in FIG. 4, the first matching circuit 34a and the first RF measurement unit 33a are disposed in this order from upstream to downstream in the first transmission line TLa. In addition, the second matching circuit 34b and the second RF measurement unit 33b are disposed in this order from upstream to downstream in the second transmission line TLb. That is, the signal information detected by the directional couplers (330a and 330b) and the VI sensors (332a and 332b) is each information of the RF signal at an output end (node) of the matching circuits (34a and 34b).

Each configuration of the RF system may be controlled by the controller 2. The controller 2 acquires, stores, and/or analyzes an electrical characteristic of the chamber 10 by controlling each configuration of the RF system. For example, the controller 2 may execute a “static characteristic determination sequence” and/or a “plasma ignition determination sequence” as described below.

### <Example of Static Characteristic Determination Sequence>

The static characteristic determination sequence is a sequence for determining the static characteristic. Here, the static characteristic is an RF reflection characteristic when the RF signal is supplied from the RF power supply 31 to the chamber 10 under a condition that a plasma is not ignited in the chamber 10. The static characteristic is, for example, the RF reflection characteristic when a signal (hereinafter, also referred to as a “low output RF signal”) having power to an extent that the plasma is not ignited from the RF power supply 31 is supplied to the chamber 10. The static characteristic may include the RF reflection characteristics for a plurality of different frequencies. That is, the static characteristic determination sequence may be processing of acquiring the RF reflection characteristic for the plurality of different frequencies and storing the RF reflection characteristic as the static characteristic. The static characteristic determination sequence may be executed at an appropriate timing such as before shipment of the plasma processing apparatus 1, at the time of initial operation after shipment (after installation on a manufacturing line), at the time of re-operation, or after a certain time has elapsed from the operation. In an embodiment, the static characteristic determination sequence may be periodically executed based on the operation time of the RF power supply 31.

In an embodiment, the static characteristic determination sequence may be executed by supplying the low output RF signal from the first RF generator 31a in a state where the plasma is not formed in the chamber 10. The static characteristic determination sequence may be executed by supplying the low output RF signal from the second RF generator 31b, and this example will be described later.

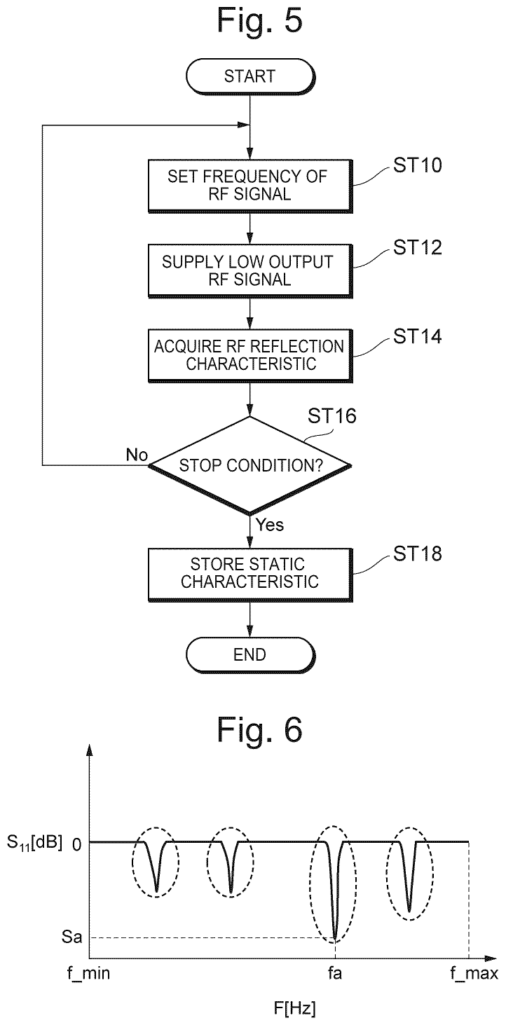

FIG. 5 is a flowchart illustrating an example of the static characteristic determination sequence. As illustrated in FIG. 5, the static characteristic determination sequence may include a step ST10 of setting the frequency of the RF signal, a step ST12 of supplying the low output RF signal, a step ST14 of acquiring the RF reflection characteristic, a step ST16 of determining whether a stop condition is satisfied, and a step ST18 of storing the static characteristic.

In the step ST10, the frequency of the low output RF signal supplied from the first RF generator 31a is set. The static characteristic determination sequence is repeated for a plurality of cycles until the stop condition (step ST16) is satisfied. In an embodiment, in a first cycle, a frequency (hereinafter, also referred to as a “minimum frequency”) smaller than a design frequency (for example, 27 MHz) of the first RF signal by, for example, 10% may be set. In a second transition cycle, a frequency slightly higher than the frequency set in the previous cycle may be set. That is, the set frequency may be increased stepwise with each cycle. Then, in a last cycle, a frequency (hereinafter, also referred to as a “maximum frequency”) higher than the design frequency by, for example, 10% may be set. In an embodiment, the frequency may be set to be decreased stepwise from the maximum frequency to the minimum frequency with increasing cycles. In an embodiment, the frequency may be appropriately set to different values for each cycle in a range from the minimum frequency to the maximum frequency. The minimum frequency and the maximum frequency are not limited to ±10% of the design frequency and may be appropriately set.

In the step ST12, the low output RF signal is supplied from the first RF generator 31a. The low output RF signal has power of an extent that does not form the plasma in the chamber 10. That is, even when the low output RF signal is supplied from the first RF generator 31a, the plasma is not formed in the chamber 10. In one example, the low output RF signal may have a power of less than 10 W, have a power of less than 5 W, or have a power of less than 1 W.

In the step ST14, the RF reflection characteristic is acquired. Specifically, the first RF measurement unit 33a (see FIGS. 3 and 4) acquires the RF reflection characteristic of the first RF signal (low output RF signal) propagating through the first transmission line TLa. The RF reflection characteristic is a parameter related to a return amount (power of a reflected wave) with respect to an output (power of a traveling wave) of the RF signal in the transmission line.

In an embodiment, the RF reflection characteristic may be determined based on the signal information detected by the first directional coupler 330a and/or the first VI sensor 332a. The signal information detected by the first directional coupler 330a includes, for example, information on the power (Pf) of the traveling wave and the power (Pr) of the reflected wave of the first RF signal (low output RF signal) at the input end or the output end (node) of the first matching circuit 34a. In addition, the signal information detected by the first VI sensor 332a includes, for example, information on the effective value (V) of the voltage, the effective value (I) of the current, and the phase difference (0) between the voltage and the current of the first RF signal (low output RF signal) at the input end or the output end (node) of the first matching circuit 34a.

In an embodiment, the RF reflection characteristic may include any one or more of the following (a) to (e) at the input end or the output end of the first matching circuit 34a.
(a) A ratio Ra (see Equation 1) of the power (Pf) of the traveling wave to the power (Pr) of the reflected wave
(b) A resistance component R (Ω) of the impedance (see Equation 2)
(c) A reflection coefficient Γ (see Equation 3)
(d) A return loss RL (dB) (see Equation 4)
(e) An S parameter S₁₁ (dB) (see Equation 5)

$$Ra = \frac{Pf}{Pr} \qquad [ Equation 1 ]$$

$$R = \frac{V}{I} cos θ \qquad [ Equation 2 ]$$

$$Γ = \sqrt{\frac{Pr}{Pf}} \qquad [ Equation 3 ]$$

$$RL = - 20 log ( Γ ) \qquad [ Equation 4 ]$$

$${S}_{11} = - RL \qquad [ Equation 5 ]$$

In the step ST16, it is determined whether the stop condition is satisfied. The stop condition may be a condition for determining whether the RF reflection characteristics are evenly obtained in the range from the minimum frequency to the maximum frequency. For example, it may be whether the number of repeated cycles of the step ST10 to the step ST14 reaches a given number. In addition, for example, it may be whether the RF reflection characteristic is obtained for the low output RF signal of a specific frequency. For example, when the frequency is increased stepwise from the minimum frequency to the maximum frequency in the repeated cycle of the step ST10, the stop condition may be whether the RF reflection characteristic is obtained for the low output RF signal of the maximum frequency. When it is determined that the stop condition is not satisfied, the processing returns to the step ST10. When it is determined that the stop condition is satisfied, the processing proceeds to the step ST18.

In the step ST18, the static characteristic is stored. Specifically, the RF reflection characteristic for each frequency acquired through the repeated cycles of the step ST10 to the step ST14 is stored in a storage 2a2 of the controller 2 as the static characteristic.

FIG. 6 is a diagram illustrating an example of the static characteristic. FIG. 6 is an example of a case where the RF reflection characteristic acquired in the step ST14 is the S parameter. In FIG. 6, a horizontal axis represents the frequency F [Hz], and a vertical axis represents the S parameter S₁₁ [dB]. In the example illustrated in FIG. 6, as illustrated by a dotted line in the drawing, a region where the S parameter S₁₁ indicates a value (distinctive RF reflection characteristic) largely deviated from zero appears at a plurality of frequencies between the minimum frequency (f_min) and the maximum frequency (f_max). It means that the more the S parameter S₁₁ deviates from zero (the larger an absolute value), the smaller the return loss of the low output RF signal is. In the example of FIG. 6, a frequency fa at which the S parameter S₁₁ is Sa is a frequency at which the return loss is minimized. The static characteristic stored in the storage 2a2 may include information on the frequency fa at which the return loss is minimized.

The static characteristic may fluctuate depending on the control condition of the RF system. For example, when a constant (reactance value) of the first matching circuit 34a is changed, the static characteristic may also fluctuate. Therefore, the static characteristic determination sequence is executed by changing the control condition of the RF system, and the static characteristic for each control condition may be stored in the storage 2a2. For example, the reactance value of the first matching circuit 34a may be changed within a given range (for example, in increments of 10%), and the static characteristic determination sequence may be executed for each reactance value. In this case, the static characteristics of each of the reactance values of the first matching circuit 34a are stored in the storage 2a2.

In an embodiment, the static characteristic determination sequence may be executed by supplying the low output RF signal from the second RF generator 31b in a state where the plasma is not formed in the chamber 10.

In an embodiment, the static characteristic determination sequence may be executed by supplying the low output RF signal from the second RF generator 31b in a state where the plasma is formed in the chamber 10. For example, the static characteristic determination sequence illustrated in FIG. 5 may be executed in a state where the plasma is formed in the chamber 10 by supplying the first RF signal (source RF signal) from the first RF generator 31a. In this case, the low output RF signal supplied from the second RF generator 31b in the step ST12 may have, for example, power of less than 1 W.

In the related art, it is necessary to connect other measuring instruments such as a vector network analyzer (VNA) to the chamber to measure the electrical characteristic of the chamber, such as the RF reflection characteristic. However, when the other measuring instruments are used, there is a limit (for example, 1 mW or less) on the power of the signal supplied to the chamber. In addition, after the plasma processing apparatus is installed and operated, it is difficult to measure the electrical characteristic in itself by connecting the other measuring instruments, and it is necessary to perform estimation calculation using an equivalent circuit.

According to an embodiment, since the RF system itself measures the electrical characteristic of the chamber 10, it is not necessary to separately connect the other measuring instruments, and there is no limit on the power of the RF signal supplied to the chamber 10 as described above. In addition, since the electrical characteristic can be measured in real time in a state where the RF system is connected to the chamber 10, the measurement accuracy may be improved as compared with the estimation calculation using the equivalent circuit. In addition, since the plasma processing apparatus 1 can periodically measure the electrical characteristic under the same conditions even after being installed and operated, it is also possible to acquire and analyze the change in the electrical characteristic over time.

### <Example of Plasma Ignition Determination Sequence>

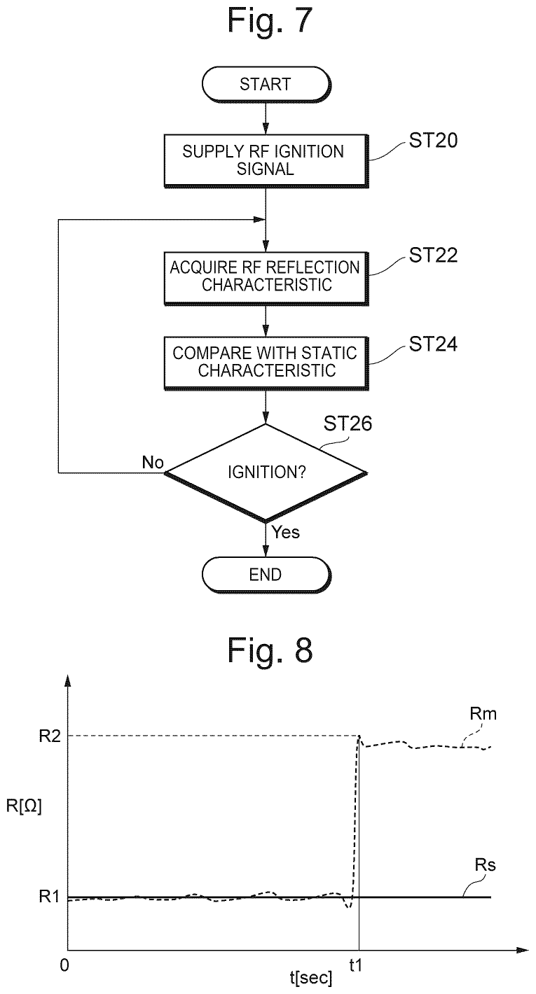

FIG. 7 is a flowchart illustrating an example of the plasma ignition determination sequence. As illustrated in FIG. 7, the plasma ignition determination sequence may include a step ST20 of supplying a source RF signal for plasma ignition (hereinafter, also referred to as an “RF ignition signal”) used for igniting the plasma in the chamber 10, a step ST22 of acquiring the RF reflection characteristic, a step ST24 of comparing the RF reflection characteristic with the static characteristic, and a step ST26 of determining whether the plasma is ignited. The steps ST20 to ST26 may be periodically executed or may be continuously executed.

In the step ST20, the RF ignition signal is supplied from the first RF generator 31a. The frequency of the RF ignition signal may be determined based on the static characteristic stored in the storage 2a2. For example, the frequency of the RF ignition signal may be selected as a frequency (for example, the frequency fa in the example illustrated in FIG. 6) at which the return loss is minimized based on the static characteristic. When a plurality of static characteristics is stored, the frequency may be determined based on the static characteristic under the same or closest control condition (for example, the same or closest reactance value of the first matching circuit 34a, or the like) as the control condition in the step ST20.

In the step ST22, the RF reflection characteristic is acquired. Specifically, the first RF measurement unit 33a (see FIGS. 3 and 4) acquires the RF reflection characteristic of the first RF signal (RF ignition signal) propagating through the first transmission line TLa. A specific example and a calculation method of the RF reflection characteristic may be the same as the specific example and the calculation method of the static characteristic determination sequence (step ST14).

In the step ST24, the comparison is made with the static characteristic (the RF reflection characteristic when the low output RF signal is supplied). Specifically, a difference between the RF reflection characteristic acquired in the step ST22 and the static characteristic stored in the storage 2a2 is calculated.

In the step ST26, the plasma ignition state is determined. That is, when the difference between the RF reflection characteristic and the static characteristic is equal to or less than a threshold value, a state where the plasma is not ignited in the chamber 10 (plasma non-ignition state) is determined. In this case, the step ST22 is executed again after a given period or continuously. On the other hand, when the difference between the RF reflection characteristic and the static characteristic is larger than the threshold value, a state where the plasma is ignited in the chamber 10 (plasma ignition state) is determined. In this case, the plasma ignition determination sequence is ended and processing is transited to the matching operation of the impedance using the first matching circuit 34a, and the matching operation is started. In the matching operation, for example, the reactance of the variable reactance element may be controlled and thus the impedance viewed from the input end of the first matching circuit 34a to the load side is the characteristic impedance (for example, 50Ω).

FIG. 8 is a diagram for describing an example of the plasma ignition determination sequence. In FIG. 8, a horizontal axis is a time t (sec) from the start of the plasma ignition determination sequence, and a vertical axis is the resistance component R (Ω) of the impedance as an example of the RF reflection characteristic. In FIG. 8, Rm is the RF reflection characteristic acquired in the step ST22. Rs is the static characteristic (resistance component R of the impedance when the low output RF signal is supplied) stored in the storage 2a2.

In the example illustrated in FIG. 8, the difference between the RF reflection characteristic (Rm) and the static characteristic (R) is almost zero for a while after the start of the plasma ignition determination sequence, and the difference (R2−R1) between the both rapidly increases and exceeds the threshold value at a time t1. In the example illustrated in FIG. 8, it is determined that the plasma is ignited in the chamber 10 at the time t1.

As described above, by executing the plasma ignition determination sequence, it is possible to accurately and quickly determine whether the plasma is ignited in the chamber 10. Accordingly, the transition from plasma ignition to the matching operation of the impedance can be performed more precisely.

In addition to the inductively coupled plasma processing apparatus 1, the present disclosure may be executed in the plasma processing apparatus 1 using any plasma source such as a capacitively coupled plasma or a microwave plasma. For example, the above-described static characteristic determination sequence and plasma ignition determination sequence may be executed in the capacitively coupled plasma processing apparatus. In this case, the capacitively coupled plasma processing apparatus includes an upper electrode and a lower electrode. The lower electrode is disposed in the substrate support, and the upper electrode is disposed above the substrate support. The first RF generator 31a is coupled to the upper electrode or the lower electrode via an impedance matching circuit, and the second RF generator 31b is coupled to the lower electrode via the impedance matching circuit. That is, the RF power supply 31 is coupled to the plasma processing chamber. In the inductively coupled plasma processing apparatus, the RF power supply being coupled to the chamber includes the RF power supply being electrically connected to a bias electrode and/or an antenna.

According to one exemplary embodiment of the present disclosure, a technique for measuring the electrical characteristic of the chamber can be provided.

The embodiments of the present disclosure further include the following aspects.

### Addendum 1

A plasma processing apparatus including:
a chamber;
an RF power supply coupled to the chamber;
a measuring instrument configured to periodically or continuously determine an RF reflection characteristic at a node between the chamber and the RF power supply;
a storage configured to store a static characteristic, the static characteristic being the RF reflection characteristic at the node when a low output RF signal is supplied from the RF power supply to the chamber, the low output RF signal having power to an extent that a plasma is not ignited in the chamber; and
a controller configured to execute a plasma ignition determination sequence, the plasma ignition determination sequence including
   comparing the RF reflection characteristic periodically or continuously determined with the static characteristic stored in the storage,
   determining that the plasma is not ignited in the chamber when a difference between the compared RF reflection characteristic and the static characteristic is equal to or less than a threshold value, and
   determining that the plasma is ignited in the chamber when the difference between the compared RF reflection characteristic and the static characteristic is larger than the threshold value.

### Addendum 2

The plasma processing apparatus according to Addendum 1, in which the RF reflection characteristic is determined from a voltage and a current detected at the node.

### Addendum 3

The plasma processing apparatus according to Addendum 1 or 2, in which the static characteristic includes the RF reflection characteristic for each frequency of the low output RF signal.

### Addendum 4

The plasma processing apparatus according to any one of Addenda 1 to 3, in which the RF reflection characteristic includes any one or more of
(a) a power ratio of a traveling wave and a reflected wave,
(b) a resistance component (Ω) of an impedance,
(c) a reflection coefficient,
(d) a return loss (dB), and
(e) an S parameter (dB) at the node.

### Addendum 5

The plasma processing apparatus according to any one of Addenda 1 to 4, further including:
an impedance matching circuit connected between the chamber and the measuring instrument.

### Addendum 6

The plasma processing apparatus according to any one of Addenda 1 to 4, further including:
an impedance matching circuit connected between the RF power supply and the measuring instrument.

### Addendum 7

The plasma processing apparatus according to any one of Addenda 1 to 6,
in which the controller is configured to further execute a static characteristic determination sequence, and
the static characteristic determination sequence includes
   supplying a plurality of low output RF signals from the RF power supply to the chamber in sequence, the plurality of low output RF signals having frequencies different from each other, respectively,
   acquiring the RF reflection characteristic for each frequency in the measuring instrument, and
   storing the acquired RF reflection characteristic for each frequency in the storage as the static characteristic.

### Addendum 8

The plasma processing apparatus according to Addendum 7, in which the static characteristic determination sequence is executed in a state where the plasma is not formed in the chamber, and the low output RF signal has power of less than 10 W.

### Addendum 9

The plasma processing apparatus according to Addendum 7, further including:
another RF power supply configured to generate a source RF signal to form the plasma in the chamber,
in which the static characteristic determination sequence is executed in a state where the plasma is formed in the chamber by the source RF signal supplied from the other RF power supply, and
the low output RF signal has power of less than 1 W.

### Addendum 10

The plasma processing apparatus according to any one of Addenda 7 to 9, in which the static characteristic determination sequence is periodically executed based on an operation time of the RF power supply.

### Addendum 11

The plasma processing apparatus according to any one of Addenda 1 to 10, in which the controller determines a frequency of an RF ignition signal used for igniting the plasma in the chamber based on the static characteristic stored in the storage.

### Addendum 12

The plasma processing apparatus according to Addendum 11, in which the frequency of the RF ignition signal is selected from one or a plurality of frequencies indicating a distinctive RF reflection characteristic in the static characteristic.

### Addendum 13

The plasma processing apparatus according to Addendum 5 or 6, in which the controller is configured to transition to a matching operation using the impedance matching circuit when it is determined that the plasma is ignited in the chamber.

### Addendum 14

A plasma processing apparatus including:
a chamber;
an RF power supply coupled to the chamber;
a measuring instrument configured to periodically or continuously determine an RF reflection characteristic at a node between the chamber and the RF power supply;
a storage; and
a controller configured to execute a static characteristic determination sequence, the static characteristic determination sequence including
   supplying a plurality of low output RF signals from the RF power supply to the chamber in sequence, the plurality of low output RF signals having frequencies different from each other, respectively, and having power to an extent that a plasma is not ignited in the chamber,
   acquiring the RF reflection characteristic for each frequency in the measuring instrument, and
   storing the acquired RF reflection characteristic for each frequency in the storage.

### Addendum 15

The plasma processing apparatus according to Addendum 14, in which the static characteristic determination sequence is executed in a state where the plasma is not formed in the chamber, and the low output RF signal has power of less than 10 W.

### Addendum 16

The plasma processing apparatus according to Addendum 14, further including:
another RF power supply configured to generate a source RF signal to form the plasma in the chamber,
in which the static characteristic determination sequence is executed in a state where the plasma is formed in the chamber by the source RF signal supplied from the other RF power supply, and
the low output RF signal has power of less than 1 W.

### Addendum 17

The plasma processing apparatus according to any one of Addenda 14 to 16, in which the static characteristic determination sequence is periodically executed based on an operation time of the RF power supply.

### Addendum 18

A plasma processing apparatus including:
a chamber;
an RF power supply coupled to the chamber;
a measuring instrument configured to periodically or continuously determine an RF reflection characteristic at a node between the chamber and the RF power supply;
a storage configured to store a static characteristic, the static characteristic being the RF reflection characteristic at the node when an RF signal is supplied from the RF power supply to the chamber under a condition in which a plasma is not ignited; and
a controller configured to execute a plasma ignition determination sequence, the plasma ignition determination sequence including
   comparing the RF reflection characteristic periodically or continuously determined with the static characteristic stored in the storage,
   determining that the plasma is not ignited in the chamber when a difference between the compared RF reflection characteristic and the static characteristic is equal to or less than a threshold value, and
   determining that the plasma is ignited in the chamber when the difference between the compared RF reflection characteristic and the static characteristic is larger than the threshold value.

### Addendum 19

The plasma processing apparatus according to Addendum 18,
in which the controller is configured to further execute a static characteristic determination sequence, and
the static characteristic determination sequence includes
   supplying a plurality of low output RF signals from the RF power supply to the chamber in sequence under a condition in which the plasma is not ignited, the plurality of low output RF signals having frequencies different from each other, respectively,
   acquiring the RF reflection characteristic for each frequency in the measuring instrument, and
   storing the acquired RF reflection characteristic for each frequency in the storage as the static characteristic.

Each of the above-described embodiments is described for the purpose of description, and it is not intended to limit the scope of the present disclosure. Each of the above-described embodiments may be modified in various ways without departing from the scope and gist of the present disclosure. For example, some configuration elements in one embodiment may be added to other embodiments. In addition, some configuration elements in one embodiment can be replaced with corresponding configuration elements in another embodiment.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

What is claimed is:

1. A plasma processing apparatus comprising:
a chamber;
an RF power supply coupled to the chamber;
a measuring instrument configured to periodically or continuously determine an RF reflection characteristic at a node between the chamber and the RF power supply;
a storage configured to store a static characteristic, the static characteristic being the RF reflection characteristic at the node when a low output RF signal is supplied from the RF power supply to the chamber, the low output RF signal having power to an extent that a plasma is not ignited in the chamber; and
controller circuitry configured to execute a plasma ignition determination sequence in which the controller circuitry is configured to
compare the RF reflection characteristic periodically or continuously determined with the static characteristic stored in the storage,
determine that the plasma is not ignited in the chamber when a difference between the compared RF reflection characteristic and the static characteristic is equal to or less than a threshold value, and
determine that the plasma is ignited in the chamber when the difference between the compared RF reflection characteristic and the static characteristic is larger than the threshold value.

2. The plasma processing apparatus according to claim 1, wherein the RF reflection characteristic is determined from a voltage and a current detected at the node.

3. The plasma processing apparatus according to claim 1, wherein the static characteristic includes the RF reflection characteristic for each frequency of the low output RF signal.

4. The plasma processing apparatus according to claim 3, wherein the RF reflection characteristic includes any one or more of
(a) a power ratio of a traveling wave and a reflected wave,
(b) a resistance component (Ω) of an impedance,
(c) a reflection coefficient,
(d) a return loss (dB), and
(e) an S parameter (dB) at the node.

5. The plasma processing apparatus according to claim 1, further comprising:
an impedance matching circuit connected between the chamber and the measuring instrument.

6. The plasma processing apparatus according to claim 1, further comprising:
an impedance matching circuit connected between the RF power supply and the measuring instrument.

7. The plasma processing apparatus according to claim 1,
wherein the controller circuitry is configured to further execute a static characteristic determination sequence in which the controller circuitry is configured to
supply a plurality of low output RF signals from the RF power supply to the chamber in sequence, the plurality of low output RF signals having frequencies different from each other, respectively,
acquire the RF reflection characteristic for each frequency in the measuring instrument, and
store the acquired RF reflection characteristic for each frequency in the storage as the static characteristic.

8. The plasma processing apparatus according to claim 7, wherein the static characteristic determination sequence is executed in a state where the plasma is not formed in the chamber, and the low output RF signal has power of less than 10 W.

9. The plasma processing apparatus according to claim 7, further comprising:
another RF power supply configured to generate a source RF signal to form the plasma in the chamber,
wherein the static characteristic determination sequence is executed in a state where the plasma is formed in the chamber by the source RF signal supplied from the other RF power supply, and
the low output RF signal has power of less than 1 W.

10. The plasma processing apparatus according to claim 7, wherein the static characteristic determination sequence is periodically executed based on an operation time of the RF power supply.

11. The plasma processing apparatus according to claim 3, wherein the controller circuitry is configured to determine a frequency of an RF ignition signal used for igniting the plasma in the chamber based on the static characteristic stored in the storage.

12. The plasma processing apparatus according to claim 11, wherein the frequency of the RF ignition signal is selected from one or a plurality of frequencies indicating a distinctive RF reflection characteristic in the static characteristic.

13. The plasma processing apparatus according to claim 5, wherein the controller circuitry is configured to transition to a matching operation using the impedance matching circuit when it is determined that the plasma is ignited in the chamber.

14. A plasma processing apparatus comprising:
a chamber;
an RF power supply coupled to the chamber;
a measuring instrument configured to periodically or continuously determine an RF reflection characteristic at a node between the chamber and the RF power supply;
a storage; and
controller circuitry configured to execute a static characteristic determination sequence in which the controller circuitry is configured to
supply a plurality of low output RF signals from the RF power supply to the chamber in sequence, the plurality of low output RF signals having frequencies different from each other, respectively, and having power to an extent that a plasma is not ignited in the chamber,
acquire the RF reflection characteristic for each frequency in the measuring instrument, and
store the acquired RF reflection characteristic for each frequency in the storage.

15. The plasma processing apparatus according to claim 14, wherein the static characteristic determination sequence is executed in a state where the plasma is not formed in the chamber, and the low output RF signal has power of less than 10 W.

16. The plasma processing apparatus according to claim 14, further comprising:
another RF power supply configured to generate a source RF signal to form the plasma in the chamber,
wherein the static characteristic determination sequence is executed in a state where the plasma is formed in the chamber by the source RF signal supplied from the other RF power supply, and
the low output RF signal has power of less than 1 W.

17. The plasma processing apparatus according to claim 14, wherein the static characteristic determination sequence is periodically executed based on an operation time of the RF power supply.

18. A plasma processing apparatus comprising:
a chamber;
an RF power supply coupled to the chamber;
a measuring instrument configured to periodically or continuously determine an RF reflection characteristic at a node between the chamber and the RF power supply;
a storage configured to store a static characteristic, the static characteristic being the RF reflection characteristic at the node when an RF signal is supplied from the RF power supply to the chamber under a condition in which a plasma is not ignited; and
controller circuitry configured to execute a plasma ignition determination sequence in which the controller circuitry is configured to
compare the RF reflection characteristic periodically or continuously determined with the static characteristic stored in the storage,
determine that the plasma is not ignited in the chamber when a difference between the compared RF reflection characteristic and the static characteristic is equal to or less than a threshold value, and
determine that the plasma is ignited in the chamber when the difference between the compared RF reflection characteristic and the static characteristic is larger than the threshold value.

19. The plasma processing apparatus according to claim 18,
wherein the controller circuitry is configured to further execute a static characteristic determination sequence in which the controller circuitry is configured to
supply a plurality of low output RF signals from the RF power supply to the chamber in sequence under a condition in which the plasma is not ignited, the plurality of low output RF signals having frequencies different from each other, respectively,
acquire the RF reflection characteristic for each frequency in the measuring instrument, and
store the acquired RF reflection characteristic for each frequency in the storage as the static characteristic.
